(19) United States
(12) Patent Application Publication
(10) Pub. No.: US 2012/0307467 A1
(43) Pub. Date: Dec. 6, 2012

(54) Oxygen-Barrier Packaged Surface Mount Device

(76) Inventors: Luis A. Navarro, San Carlos, CA (US); Mario G. Sepulveda, Newark, CA (US); Patrick J. Hibbs, Murphy, TX (US); Martin G. Pineda, Fremont, CA (US); Martyn A. Matthiesen, Fremont, CA (US); Anthony Vranicar, Santa Clara, CA (US); Dong Yu, Fremont, CA (US)

(21) Appl. No.: 13/153,368

(22) Filed: Jun. 3, 2011

(51) Int. Cl. H05K 7/10; B32B 38/10

(52) U.S. Cl. 361/767; 156/247; 361/808

(57) ABSTRACT

An electrical component includes a plurality of core devices arranged within a housing so as to be electrically isolated from one another. For each of the plurality of core devices, a first contact pad and a second contact pad is formed on an outside surface of the housing. The first and second contact pads are electrically connected to a respective core device of the plurality of core devices.

### CROSS-REFERENCE TO RELATED APPLICATIONS

This application is related to U.S. application Ser. No. 12/460,349, filed Jul. 17, 2009, which is incorporated by reference it its entirety.

### BACKGROUND

1. Field

The present invention relates generally to electronic circuitry. More specifically, the present invention relates to an oxygen-barrier packaged surface mount device.

2. Introduction

Surface mount devices (SMDs) are utilized in electronic circuits because of their small size. Generally, SMDs comprise a core device embedded within a housing material, such as plastic or epoxy. For example, a core device with resistive properties may be embedded in the housing material to produce a surface mount resistor.

One disadvantage with existing SMDs is that the materials utilized to encapsulate the core device tend to allow oxygen to permeate into the core device itself. This could be adverse for certain core devices. For example, the resistance of a positive temperature coefficient core device tends to increase over time if oxygen is allowed to enter the core device. In some cases, the base resistance may increase by a factor of five (5), which may take the core device out of spec.

### SUMMARY

In one aspect, a method for producing a surface mount device includes providing a plurality of layers including a first layer that is B-staged and a second layer that defines an opening for receiving a core device. A core device may be inserted into the opening defined by the second layer. Then the second layer and the core device may be covered by the first layer that is B-staged. The first layer and second layer are then cured until the first layer that is B-staged becomes C-staged. The core device is substantially surrounded by an oxygen-barrier material with an oxygen permeability of less than approximately 0.4 cm³·mm/m²·atm·day (1 cm³·mil/100 in2·atm·day).

In a second aspect, a method for producing a surface mount device includes providing a substrate layer. The substrate layer includes a first and second conductive contact pad. A core device is fastened to the first contact pad such that a bottom conductive surface of the core device is in electrical contact with the first contact pad. A conductive clip is fastened over a top surface of the core device and the second contact pad to provide an electrical path from the top surface of the core device to the second pad. An A-staged material is injected around the core device and the conductive clip. The SMD is cured until the A-staged material becomes C-staged. Alternatively, the A-staged material may be partially cured to a B-staged level. This may be desired if some intermediate process is required before full cure. The core device is substantially surrounded by an oxygen-barrier material.

In a third aspect, a method for producing a surface mount device includes providing a first and second substrate layer. The first and second substrate layers each include a generally L-shaped interconnect that defines a surface mount device contact surface along a top surface of the substrate, a middle region that extends through the substrate layer, and a core device contact that extends along a bottom surface of the substrate layer. A top surface of a core device is fastened to the core device contact of the interconnect of the first substrate. A bottom surface of the core device is fastened to the core device contact of the interconnect of the second substrate. An A-staged material is injected around the core device and cured until the material becomes C-staged. The core device is substantially surrounded by an oxygen-barrier material.

In a fourth aspect, a surface mount device comprises a core device with a top surface and a bottom surface. A C-staged oxygen-barrier insulator material substantially encapsulates the core device. A first contact pad and a second contact pad are disposed on an outside surface of the oxygen-barrier insulator material. The first contact pad and the second contact pad are configured to provide an electrical path from the top surface of the core device and the bottom surface of the core device to a first and second pad, respectively, defined by the a substrate and/or printed circuit board.

In a fifth aspect, an electrical component includes a plurality of core devices arranged within a housing so as to be electrically isolated from one another. For each of the plurality of core devices, a first contact pad and a second contact pad is formed on an outside surface of the housing. The first and second contact pads are electrically connected to a respective core device of the plurality of core devices.

In a sixth aspect, a method for producing an electrical component includes providing a plurality of layers including a first layer that is B-staged and a second layer that defines a plurality of openings for receiving a plurality of core devices. The method also includes inserting the plurality of core devices in the plurality of openings defined by the second layer, covering the second layer and the plurality of core devices with the first layer that is B-staged, and curing the first layer and second layer until the first layer that is B-staged becomes C-staged. The cured first and second layers are then separated into housing portions that each include a plurality of core devices. The core devices are electrically isolated from one another.

In a seventh aspect, a circuit includes a first electrical component. The first electrical component includes a plurality of core devices arranged within a housing so as to be electrically isolated from one another. For each of the plurality of core devices, a first contact pad and a second contact pad are formed on an outside surface of the housing and electrically connected to a core device of the plurality of core devices. Respective input circuits are coupled to respective first contact pads of the core devices. Respective output circuits are coupled to respective second contact pads of the core devices.

### BRIEF DESCRIPTION OF THE DRAWINGS

FIGS. 1A and 1B are top and bottom views, respectively, of one implementation of a surface mount device (SMD);

FIG. 1C is a cross-sectional view of the SMD of FIG. 1A taken along section A-A of FIG. 1A;

FIG. 2 illustrates an exemplary group of operations that may be utilized to manufacture the SMD described in FIGS. 1A-1C;

FIG. 3 illustrates a top, middle, and bottom layer of the SMD of FIGS. 1A-1C;

FIG. 4A is a cross-sectional view of the top layer, middle layer, and bottom layer of FIG. 3 taken along section Z-Z of FIG. 3 before the layers are cured;

FIG. 4B is a cross-sectional view of the top layer, middle layer, and bottom layer of FIG. 3 taken along section Z-Z of FIG. 3 after the layers are cured;

FIG. 4C is a perspective view of cured layers with slots formed in-between core devices encapsulated in the cured layers;

FIG. 4D is a perspective view of cured layers with holes formed in between core devices encapsulated in the cured layers;

FIG. 5A is a top-perspective view of another implementation of a surface mount device (SMD);

FIG. 5B is a cross-sectional view of the SMD of FIG. 5A taken along section A-A;

FIG. 6 illustrates an exemplary group of operations that may be utilized to manufacture the SMD described in FIGS. 5A and 5B;

FIG. 7 illustrates layers of the SMD of FIGS. 5A and 5B;

FIGS. 8A and 8B are top and bottom views, respectively, of a third implementation of a surface mount device (SMD);

FIG. 8C is a cross-sectional view of the SMD of FIG. 8A taken along section A-A;

FIG. 9 illustrates an exemplary group of operations that may be utilized to manufacture the SMD described in FIGS. 8A-8C;

FIG. 10 illustrates an exemplary electrical component that includes four electrically isolated core devices;

FIG. 11 illustrates an exemplary circuit diagram with electrical components that include the exemplary electrical component of FIG. 10; and

FIG. 12 illustrates exemplary operations that may be utilized to manufacture the electrical component of FIG. 10.

### DETAILED DESCRIPTION

To overcome the problems described above, various implementations of SMDs that include an oxygen-barrier material are disclosed. The various implementations generally utilize insulator materials to protect a core device from the effects of oxygen and other impurities. In some implementations, the insulator material may correspond to one of the oxygen-barrier materials described in U.S. patent application Ser. No. 12/460,338, filed Jul. 17, 2009, which is hereby incorporated by reference in its entirety. The oxygen-barrier material may have an oxygen permeability of less than approximately 0.4 cm³·mm/m²·atm·day (1 cm³·mil/100 in2·atm·day), measured as cubic centimeters of oxygen permeating through a sample having a thickness of one millimeter over an area of one square meter. The permeation rate is measured over a 24 hour period, at 0% relative humidity, and a temperature of 23° C. under a partial pressure differential of one atmosphere). Oxygen permeability may be measured using ASTM F-1927 with equipment supplied by Mocon, Inc., Minneapolis, Minn., USA.

The insulator material generally comprises one or more thermosetting polymers, such as an epoxy. The insulator material may exist in one of three physical states, an A-staged, B-staged, and a C-staged state. An A-staged state, is characterized by a composition with a linear structure, solubility, and fusibility. In certain embodiments, the A-staged composition may be a high viscosity liquid, having a defined molecular weight, and comprised of largely unreacted compounds. In this state, the composition will have a maximum flow (in comparison to a B-staged or C-staged material). In certain embodiments, the A-staged composition may be changed from an A-staged state to either a B-staged state or a C-staged state via either a photo-initiated reaction or thermal reaction.

A B-staged state is achieved by partially curing an A-stage material, wherein at least a portion of the A-stage composition is crosslinked, and the molecular weight of the material increases. Unless indicated otherwise, B-stageable compositions can be achieved through either a thermal latent cure or a UV-cure. In certain embodiments, the B-stageable composition is effectuated through a thermal latent cure. B-staged reactions can be arrested while the product is still fusible and soluble, although having a higher softening point and melt viscosity than before. The B-staged composition contains sufficient curing agent to affect crosslinking on subsequent heating. In certain embodiments, the B-stage composition is fluid, or semi-solid, and, therefore, under certain conditions, can experience flow. In the semi-solid form, the thermosetting polymer may be handled for further processing by, for example, and operator. In certain embodiments, the B-stage composition comprises a conformal tack-free film, workable and not completely rigid, allowing the composition to be molded or flowed around an electrical device.

A C-staged state is achieved by fully curing the composition. In some embodiments, the C-staged composition is fully cured from an A-staged state. In other embodiments, the C-staged composition is fully cured from a B-staged state. Typically, in the C-stage, the composition will no longer exhibit flow under reasonable conditions. In this state, the composition may be solid and, in general, may not be reformed into a different shape.

Another formulation of insulator material is a prepreg formulation. Prepreg formulations generally correspond to a B-staged formulation with a reinforcing material. For example, fiberglass or a different reinforcing material may be embedded within the B-stage formulation. This enables the manufacture of sheets of B-staged insulator material.

The insulator materials described above enable the production of surface mount devices or other small devices that exhibit a low oxygen permeability. For example, the insulator material enables producing low oxygen permeability surface mount devices with wall thicknesses less than 0.35 mm (0.014 in).

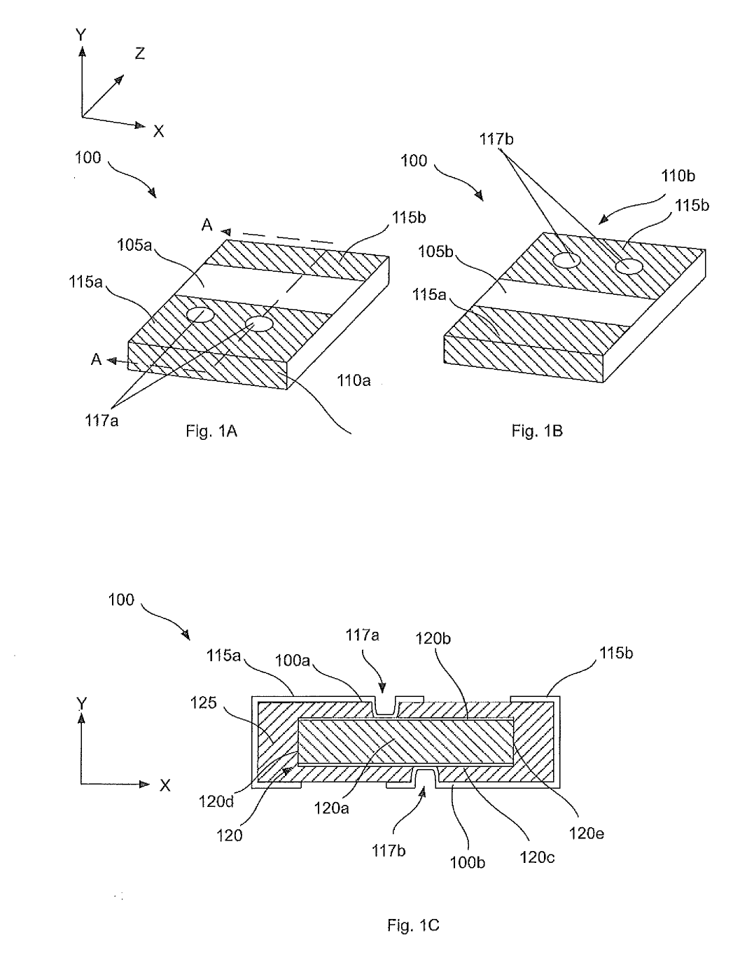

FIGS. 1A and 1B are top and bottom views, respectively, of one implementation of a surface mount device (SMD) 100. The SMD 100 includes a generally rectangular body with a top surface 105a, a bottom surface 105b, a first end 110a, a second end 110b, a first contact pad 115a, and a second contact pad 115b. The first contact pad 115a and the second contact pad 115b extend from the top surface 105a of the SMD 100, over the first end 110a and second end 110b, respectively, and over the bottom surface 105b. The first contact pad 115a defines a first pair of openings 117a and the second contact pad 115b defines a second pair of openings 117b, as shown in FIGS. 1A and 1B, respectively. The first and second pairs of openings 117a, 117b are configured to bring the first and second contact pads 115a, 115b into electrical communication with an internally located cored device 120, as shown in FIG. 1C. In one implementation, the size of the SMD 100 may be about 3.0 mm by 2.5 mm by 0.7 mm (0.120 in by 0.100 in by 0.028 in) in an X, Y, and Z direction, respectively.

FIG. 1C is a cross-sectional view of the SMD 100 of FIG. 1A taken along section A-A of FIG. 1A. The SMD 100 includes a first contact pad 115a, a second contact pad 115b, a core device 120, and an insulator material 125. The core device 120 may correspond to a device that has properties that deteriorate in the presence of oxygen. For example, the core device 120 may correspond to a low-resistance positive temperature coefficient (PTC) device comprising a conductive polymer composition. The electrical properties of conductive polymer composition tend to deteriorate over time. For example, in metal-filled conductive polymer compositions, e.g. those containing nickel, the surfaces of the metal particles tend to oxidize when the composition is in contact with an ambient atmosphere, and the resultant oxidation layer reduces the conductivity of the particles when in contact with each other. The multitude of oxidized contact points may result in a 5× or more increase in electrical resistance of the PTC device. This may cause the PTC device to exceed its original specification limits. The electrical performance of devices containing conductive polymer compositions can be improved by minimizing the exposure of the composition to oxygen.

The core device 120 may include a body 120a, a top surface 120b, and a bottom surface 120c. The body 120a may have a generally rectangular shape, and in some implementations, may be about 0.3 mm (0.012 in) thick along a Y axis, 2 mm (0.080 in) long along an X axis, and 1.5 mm (0.060 in) deep along a Z axis. The top and bottom surfaces 120b and 120c may comprise a conductive material. For example, the top and bottom surfaces 120b and 120c may comprise a 0.025 mm (0.001 in) thick layer of nickel (Ni) and/or a 0.025 mm (0.001 in) thick layer of copper (Cu). The conductive material may cover the entire top and bottom surfaces 120b and 120c of the core device 120.

In some implementations, the insulator 125 may correspond to an oxygen-barrier material, such as one of the oxygen-barrier materials described in U.S. patent application Ser. No. 12/460,338, filed Jul. 17, 2009. The oxygen-barrier material may prevent oxygen from permeating into the core device, thus preventing deterioration of the properties of the core device. The thickness of the insulator 125 from the top surface 120b of the core device 120 to the top surface 100a of the SMD 100 along a Y axis may be in the range of 0.01 to 0.125 mm (0.0004 to 0.005 in), e.g. about 0.056 mm (0.0022 in). The thickness of the insulator 125 from an end of the core device 120d and 120e to an end of the SMD 100 along an X axis may be in the range of 0.025 to 0.63 mm (0.001 to 0.025 in), e.g. about 0.056 mm (0.0022 in).

The first and second contact pads 115a and 115b are utilized to fasten the SMD 100 to a printed circuit board or substrate (not shown). For example, the SMD 100 may be soldered to pads on a printed circuit board and/or substrate via one surface of the first and second contact pads 115a and 115b. As described above, the first contact pad 115a may define a first pair of openings 117a and the second contact pad 115b may define a second pair of openings 117b. On the first contact pad 115a, the first pair of openings 117a may extend from the top surface 100a of the SMD 100 to the top surface 120b of the core device 120. On the second contact pad 115b, the second pair of openings 117b may extend from the bottom surface 100b of the SMD 100 to the bottom surface 120c of the core device 120. The interior of each opening of the first and second pairs of openings 117a, 117b may be plated with a conductive material, such as copper. The plating may provide an electrical pathway from the outside of the SMD 100 to the core device 120.

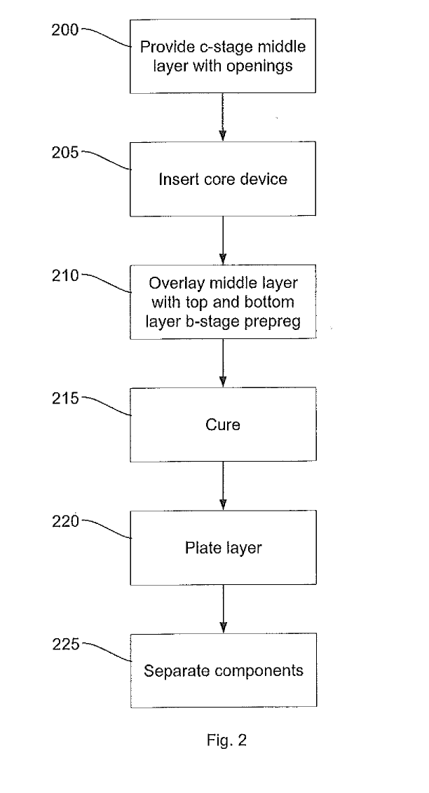

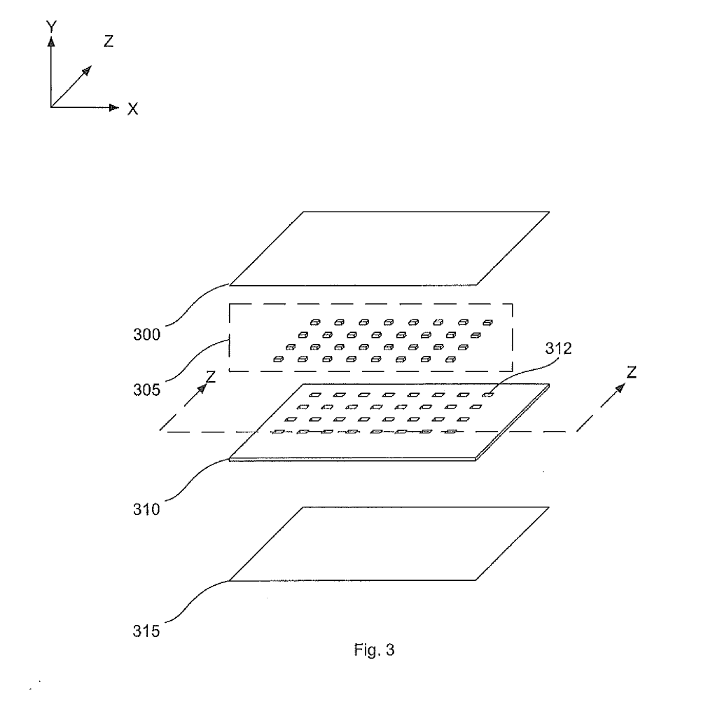

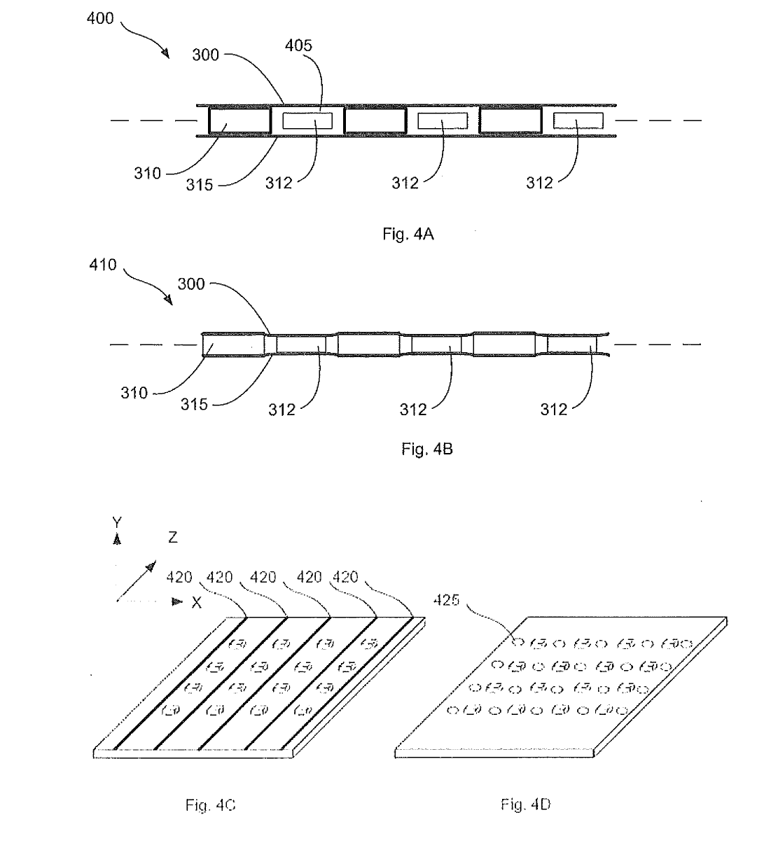

FIG. 2 illustrates an exemplary group of operations that may be utilized to manufacture the SMD described in FIGS. 1A-1C. The operations shown in FIG. 2 are described with reference to the structures illustrated in FIGS. 3, 4A, and 4B. At block 200, a C-staged middle layer 310 may be provided and openings 312 may be defined in the middle layer, as shown in FIG. 3.

Referring to FIG. 3, the middle layer 310 may correspond to a generally planar sheet of C-staged insulator material. The thickness of the sheet is generally at least as thick as the core device 120, and may be, for example, about 0.38 mm (0.015 in) in the Y direction.

The openings 312 in the sheet may be sized to receive a core device 305, such as the core device 120 described above in FIG. 1C. In some implementations, the size of the openings 312 may be about 2.0 mm by 1.5 mm by 0.36 mm (0.080 in by 0.060 in by 0.014 in), in the X, Y, and Z directions, respectively.

In some implementations, the openings 312 are cut out from the middle layer 310. For example, the openings 312 may be cut out with a laser. In other implementations, the middle layer 310 is fabricated via a mold that defines the openings 312. In yet other implementations, a punch is utilized to punch the openings 312 in the middle layer 310.

Referring back to FIG. 2, at block 205, core devices 305 may be inserted into the openings 312. Each core device 305 may correspond to the core device 120 described above in conjunction with FIGS. 1A-1C. As shown in FIG. 3, the core devices 305 may be inserted into corresponding openings 312 in the middle layer 310. The core devices 305 may be inserted into the openings 312 by hand, be placed in the openings 312 with pick-and-place machinery, vibratory sifting table, and/or via a different process.

Referring back to FIG. 2, at block 210, the middle layer 310 with the inserted core devices 305 may be placed between two insulator layers 300 and 315, as shown in FIG. 3.

Referring to FIG. 3, the middle layer 310 and the core device 305 may be inserted between a top insulator layer 300 and a bottom layer insulator layer 315. The top and bottom insulator layers 300 and 315 may correspond to a prepreg B-staged formulation, as described above. The top and bottom insulator layers 300 and 315 may have a generally planar shape and may have a thickness of about 0.056 mm (0.0022 in) in the Y direction. The width and depth of the top and bottom insulator layers 300 and 315 in the X and Z directions, respectively, may be sized to overlap all of the openings 312 defined in the middle layer 310.

Referring back to FIG. 2, at block 215, the top, middle, and bottom layers 300, 310 and 315 may be cured. In some implementations, a metal layer (not shown) may be placed over the top insulator layer 300 and under the bottom insulator layer 315. The metal layers may correspond to a copper foil. The various layers may then be subjected to a curing temperature, and pressure may be applied to the various layers to compress the layers. For example, a vacuum press or other device may be utilized to compress the various layers against one another.

The curing temperature may be about 175° C. and the amount of pressure applied may be about 1.38 MPa (200 psi).

FIGS. 4A and 4B are cross-sectional views 400 and 410 of the top insulator layer 300, middle layer 310, and bottom insulator layer 315 taken along section Z-Z of FIG. 3, before and after curing of the various layers, respectively. In FIG. 4A, a gap 405 is defined between the top and bottom layers 300 and 315 and the core devices 312 are inserted in the openings of the middle layer 310. In FIG. 4B, after curing, the top and bottom layers 300 and 315 are compressed such that the gap 404 is reduced by the thickness of the reinforcing material of the B-staged prepregs.

Apertures for plating regions that will ultimately correspond to the ends of a PTC device may be defined between the cured layers. In one implementation, slots that extend through the layers are formed between rows of devices. For example, referring to FIG. 4C the direction of the slots 420 may run in the Z direction. The slots 420 may be formed via a laser, mechanical milling, punching, or other process.

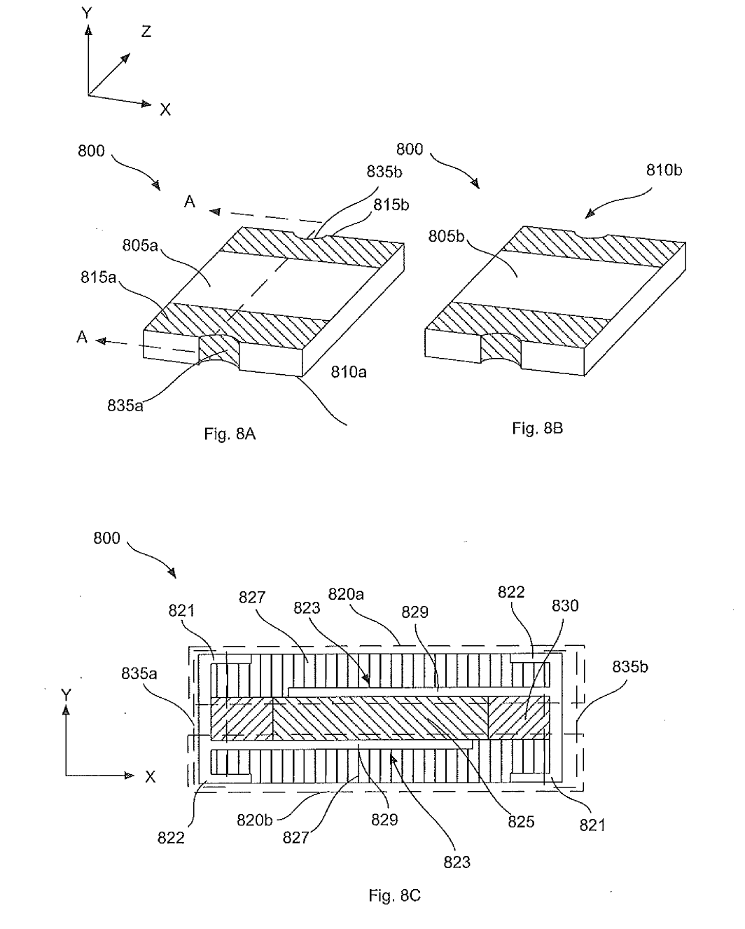

In a different implementation, holes 425 may be formed between devices and shared between devices in a column that runs in the X direction, as shown in FIG. 4D. The holes 425 may be formed by laser, mechanical drilling, or a different process. In a later operation, the interior surfaces of the holes 425 are plated to produce channel ends such as the channel ends 835a and 835b shown on the PTC device 800 in FIGS. 8A and 8B, and described below.

At block 220, a metallization layer (not shown) may be formed on the top and bottom layers 300 and 315 and also the apertures that expose the ends of the individual PTC devices. For example, a copper and/or nickel layer may be deposited on the top and bottom layers. The metallization layer may be etched to define contact pads for an SMD. The contact pads may correspond to the contact pads 115a and 115b of FIG. 1. Openings may be defined in the plating layer. The openings may correspond to one or more of the openings of the first and second pairs of openings 117a and 117b of FIG. 1. The openings may be defined via a drill, laser, or other process. The interior region of the openings may be plated to provide an electrical pathway between the contact pads and the core devices. Where slots are formed between rows of devices, the ends of the PTC device 110a and 110b (FIG. 1A) may be metalized, as shown in FIG. 1A and FIG. 1B. Where holes are formed between devices, the interior surface of the holes may be metalized. In this case, the ends of the PTC device may appear similar the channels ends 835a and 835b shown on the PTC device 800 in FIGS. 8A and 8B, and described below.

At block 225, the consolidated structure of cured layers may be cut with a saw, laser, or other tool to produce individual SMDs.

In some implementations, the top layer, middle layer, and bottom layer 300, 310 and 315 correspond to an oxygen-barrier material, as described above. The oxygen-barrier properties of the top, middle, and bottom layers prevent oxygen from entering the core device, thus preventing adverse changes in the properties of the core device. For example, the oxygen-barrier insulator material may prevent the 5× increase in resistance noted above that would otherwise occur in a PTC device.

In other implementations, the layers from which the insulator is comprised of may comprise a material that does not exhibit oxygen-barrier properties. In these implementations, the core device may be coated with a liquid form of oxygen-barrier material, such as one of the barrier materials described in U.S. Pat. No. 7,371,459 B2, issued on May 13, 2008, which is hereby incorporated by reference in its entirety. The liquid form of oxygen-barrier material may include a solvent that enables depositing the oxygen-barrier material on the core device. The solvent may then evaporate, leaving a hardened form of the oxygen-barrier material on the core device. The core device may then be packaged as described in FIG. 2 above.

Alternatively, a barrier layer as described in U.S. Pat. No. 4,315,237, issued on Feb. 9, 1982, which is hereby incorporated by reference in its entirety, may be utilized to encapsulate the core device.

It will be understood by those skilled in the art that the SMD described above may be manufactured in different ways without departing from the scope of the claims. For example, in one alternative implementation, the SMD may be manufactured by providing a C-staged bottom layer with recesses for receiving core devices rather than openings. The C-staged bottom layer may then be covered by a B-staged top layer and cured as described above.

In yet other implementations, the core devices may be placed into the openings and/or recesses defined by the C-staged layer described above. Then an A-staged oxygen-barrier material may be forced into the openings and/or recesses to cover the core devices. For example, the A-staged layer may be squeezed into the openings and/or recesses. Finally, B-staged layers may be placed above and/or below the C-staged layer and the assembly may be cured as described above.

In yet another implementation, the core devices may be encapsulated within the openings and/or recess as described above and an oxygen-barrier material that is A-staged, B-staged, C-staged, or any combination thereof may be configured to cover the assembly covering the core devices.

In yet another implementation, the core devices may be inserted within the openings and/or recesses as described above and ultraviolet (UV) radiation curable oxygen-barrier material may be configured to cover the assembly covering the core devices. The assembly may then be thermally cured as described above.

One of ordinary skill will appreciate that the various implementations described above may be combined in various ways to produce an SMD with oxygen-barrier characteristics.

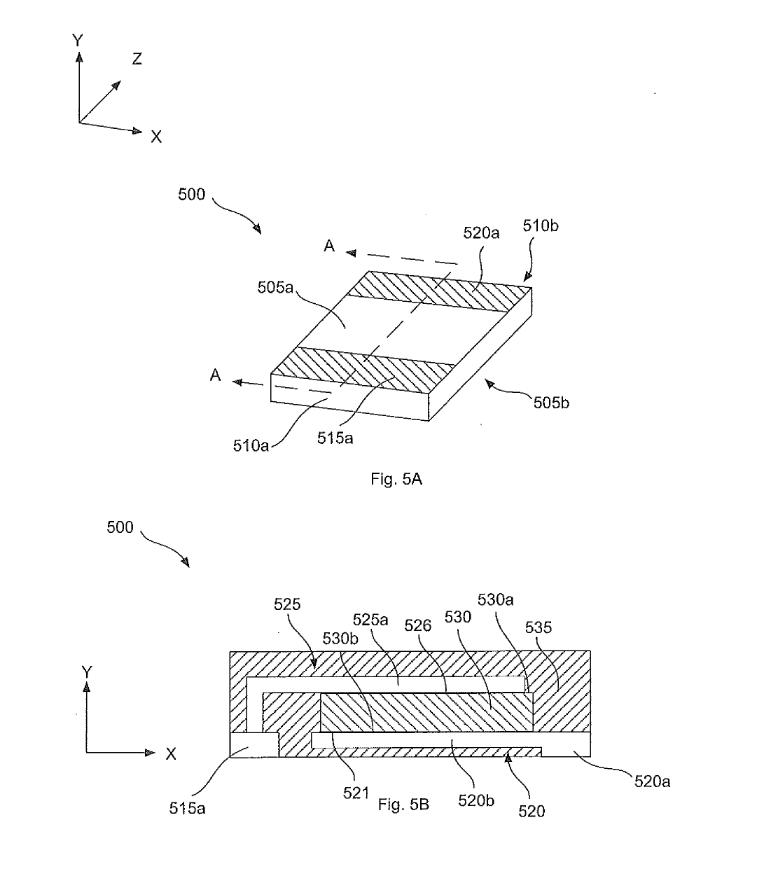

FIG. 5A is a bottom perspective view of another implementation of a surface mount device (SMD) 500. The SMD 500 includes a generally rectangular body with a top surface 505a, a bottom surface 505b, a first end 510a, a second end 510b, a first contact pad 515a, and a second contact pad 515b. The first and second contact pads 515a and 515b are disposed on opposite ends of the bottom surface 505a, and in some implementations, are separated from one another by a distance of about 2.0 mm (0.080 in). The size of the SMD 100 may be about 3.0 mm by 2.5 mm by 0.71 mm (0.120 in by 0.100 in by 0.028 in) in the X, Y, and Z directions, respectively.

FIG. 5B is a cross-sectional view of the SMD 500 of FIG. 5A taken along section A-A. The SMD 500 includes a first contact pad 515a, a contact interconnect 520, a core device 530, a clip interconnect 525, and an insulator material 535. The core device 530 may correspond to a device that has properties that deteriorate in the presence of oxygen, such as the PTC device described above. The core device 530 may comprise a top surface 530a, and a bottom surface 530b. The core device 530 may be generally rectangular and may have a thickness of about 2.0 mm by 0.30 mm by 1.5 mm (0.080 in by 0.012 in by 0.060 in) in the X, Y, and Z directions, respectively. The top and bottom surfaces 530a and 530b may comprise a conductive material. For example, the top and bottom surfaces 530a and 530b may comprise a 0.025 mm (0.001 in) thick layer of nickel (Ni) and/or a 0.025 mm (0.001 in) thick layer of copper (Cu). The conductive material may cover the entire top and bottom surfaces 530a and 530b of the core device.

In some implementations, the insulator 535 may correspond to a C-staged oxygen-barrier material, such the oxygen-barrier material described above. The oxygen-barrier material may prevent oxygen from permeating into the core device.

The contact interconnect 520 may include a contact pad 520a, hereinafter referred to as the second contact pad 520a, and an extension 520b. The extension 520b includes a top surface 521 in electrical contact with the bottom surface 530b of the core device 530. The extension 520b may be about 2.0 mm (0.080 in) in the X direction and 0.13 mm (0.005 in) in the Z direction.

The first and second contact pads 515a and 520a are utilized to fasten the SMD 500 to a printed circuit board or substrate (not shown). For example, the SMD 500 may be soldered to pads on a printed circuit board and/or substrate via the first and second contact pads 515a and 520a.

The clip interconnect 525 is generally L-shaped and provides an electrical path between the first contact pad 515a and the top surface 530a of the core device 530. The clip interconnect 525 includes a horizontal section 525a. The horizontal section 525a of the clip 525 may include a bottom surface 526 in electrical contact with the top surface 530a of the core device 530. The bottom surface 526 of the horizontal section 525a may be about 2.5 mm (0.100 in) in the X direction and 1.0 mm (0.040 in) in the Z direction.

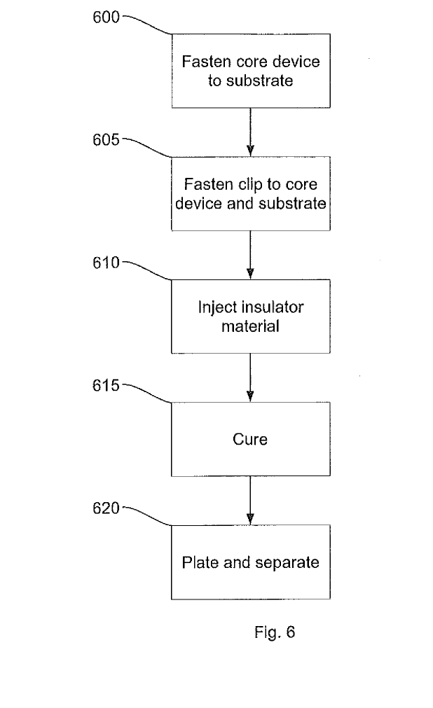

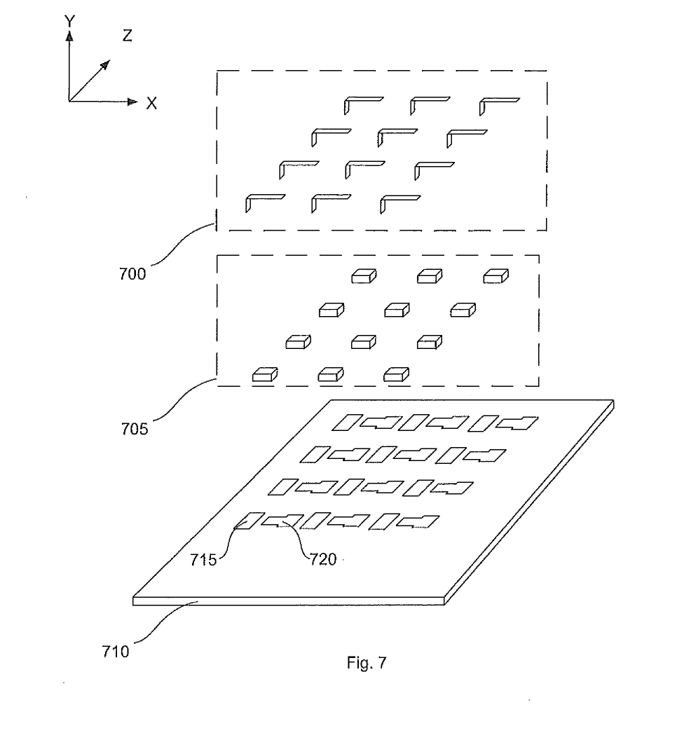

FIG. 6 illustrates an exemplary group of operations that may be utilized to manufacture the SMD described in FIGS. 5A and 5B. The operations shown in FIG. 6 are described with reference to the structures illustrated in FIG. 7. At block 600, core devices 705 may be fastened to a substrate 710. Each core device 705 may correspond to a PTC device, as described above. The core devices 705 may be placed over the substrate 705. The core devices 705 may be fastened by hand, via pick-and-place machinery, and/or via a different process.

The substrate 710 may correspond to a metal lead frame or a printed circuit board that defines a plurality of contact pads 715 and contact interconnects 720. The contact pads 715 and contact interconnects 720 may correspond to the contact pad 515a and the contact interconnect 520 in FIG. 5. The thickness of the substrate 710 may be about 0.2 mm (0.008 in) in the Y direction. The core devices 705 may be fastened to the contact interconnects 720 defined on the substrate 710. For example, the bottom surfaces of the core devices 705 may be soldered to the top surfaces of the extensions on the contact interconnects 720.

At block 605, the clip interconnects 705 may be fastened to the core device and the substrate. The horizontal sections of the clip interconnects 700 may be fastened to the top surfaces of the core devices 705, and the opposite end of the clip interconnects 700 may be fastened to the contact pads 715. For example, the clip interconnects 700 may be soldered to the top surfaces of the core devices 705 and the contact pads 715.

At block 610, an insulator material may be injected around the core devices 705 and the clip interconnects 700. The insulator material may correspond to an A-staged material.

At block 615, the insulator material may be cured. For example, a curing temperature of 150° C. may be applied to the insulator material to convert the material into a C-staged formulation.

At block 620, individual SMDs may be separated from the cured configuration. For example, the SMDs may be cut from the cured configuration with a saw, laser, or other tool.

In some implementations, the insulator material may correspond to an oxygen-barrier material, as described above. In other implementations, the insulator material comprises a material that does not exhibit oxygen-barrier properties. Rather, the core device may be coated with a liquid form of an oxygen-barrier material, such as the liquid form of oxygen-barrier material described above, before the insulator material is injected around the core device.

In alternative implementations, the clip interconnects 705 may be integral to the substrate. For example, the clip interconnects 705 may be integral to a metal lead frame.

In other alternative implementations, the clip interconnects 705 may be configured to provide an elastic force against the core devices 705. The core devices 705 may be inserted in between the horizontal sections 525a (FIG. 5) of the clip interconnects 705 and the contact pads 520a (FIG. 5) of the contact interconnects 720. The elastic force of the clip interconnects 705 may be strong enough to secure the core devices 705 in position and thereby provide a secure electrical contact with the core devices. After insertion of the core devices 705, the operations from block 610 (FIG. 6) may be performed.

FIGS. 8A and 8B are top and bottom views, respectively, of a third implementation of a surface mount device (SMD) 800. The SMD 800 includes a generally rectangular body with a top surface 805a, a bottom surface 805b, a first end 810a, a second end 810b, a first contact pad 815a, and a second contact pad 815b. The first and second contact pads 815a and 815b extend from the top surface 805a of the SMD 800, through end channels 835a and 835b, respectively, and over the bottom surface 805b. The size of the SMD 800 may be about 3.0 mm by 2.5 mm by 0.71 mm (0.120 in by 0.100 in by 0.028 in) in X, Y, and Z directions, respectively.

FIG. 8C is a cross-sectional view of the SMD 800 of FIG. 8A taken along section A-A. The SMD 800 includes a top substrate layer 820a, a bottom substrate layer 820b, a core device 825, an insulator material 830, a first end channel 835a, and a second end channel 835b. The core device 825 may correspond to a device that has properties that deteriorate in the presence of oxygen. For example, the core device 825 may correspond to the core devices described above.

Each of the top and bottom substrate layers 820a and 820b includes a first contact surface 821, a contact interconnect 823, and a substrate core 827. The contact interconnect 823 may be a generally L-shaped conductive material and may define a second contact surface 822 on one end and a component contact surface 829 on the opposite end. The contact surface 822 of the contact interconnect 823 may be defined on an outer side of the top or bottom substrate layer 820a and 820b that faces away from the core device 825, and the component contact surface 829 may be defined on an inner side of the top or bottom substrate layer 820a and 820b that faces the core device 825. The substrate core 827 may correspond to a hardened epoxy fill or a fiberglass circuit board material.

The component contact surface 829 of the upper substrate layer 820a is sized to cover the top side of the core device 825. The component contact surface 829 of the lower substrate layer 820b is sized to cover the bottom side of the core device 825.

The first and second channels 835a and 835b are disposed on opposite ends of the SMD 800. The first channel 835a may extend from the first contact surface 821 on the upper substrate 820a to the second contact surface on the lower substrate 820b. The second channel 835b may extend from the first contact surface 821 on the lower substrate 820b to the second contact surface 822 on the upper substrate 820a. The interior surface of the channels 835a and 835b may be plated to provide an electrical path between the contact pads on the upper and lower substrates 820a and 820b, respectively.

The first contact surface 821 on the upper substrate 820a and the second contact surface 822 on the lower substrate 820b may define the first contact pad 815a in FIG. 8A. The first contact surface 821 on the lower substrate 820b and the second contact surface 822 on the upper substrate 820a may define the second contact pad 815b in FIG. 8A. The first and second contact pads 815a and 815b are utilized to fasten the SMD 800 to a printed circuit board or substrate (not shown). For example, the SMD 800 may be soldered to pads on a printed circuit board and/or substrate via the contact pads 815a and 815b.

In some implementations, the insulator 830 may correspond to a C-staged oxygen-barrier material, such as the C-staged oxygen-barrier material described above. The insulator 830 may be utilized to fill in the region in between the ends of the core 825 device and ends of the SMD 800.

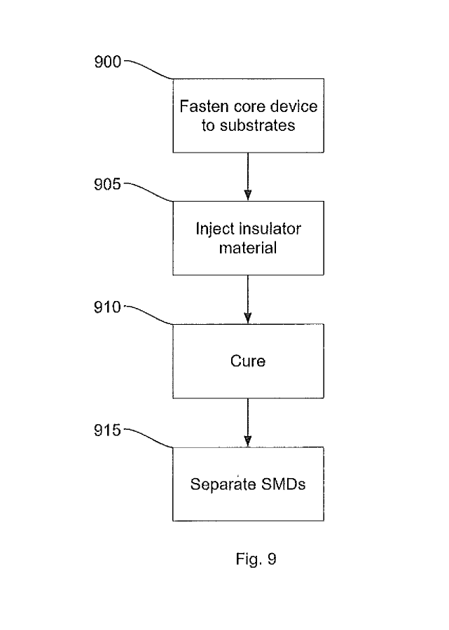

FIG. 9 illustrates an exemplary group of operations that may be utilized to manufacture the SMD described in FIGS. 8A-8C. At block 900, a core device may be fastened in between an upper and lower substrate. The core device may correspond to a PTC device, as described above. In some implementations, an array of core devices may be fastened to the upper and lower substrates. The core devices may be fastened by hand, via pick-and-place machinery, and/or via a different process.

The substrate may correspond to a printed circuit board with conductive layers on a two sides, as described above. The thickness of the substrate may be about 0.076 mm (0.003 in) in the Y direction. The core devices may be fastened to component contact surfaces defined on the respective substrates.

At block 905, an insulator material may be injected around the core device and clip interconnect. The insulator material may correspond to an A-staged material, as described above.

At block 910 the insulator material may be cured at a curing temperature. For example, a curing temperature of 150° C. may be applied to the insulator material to convert the material into a C-staged formulation.

At block 915, individual SMDs may be separated from the cured configuration. For example, the SMDs may be cut from the cured configuration with a saw, laser, or other tool.

In some implementations, the insulator material may correspond to an oxygen-barrier material, as described above. In other implementations, the insulator material comprises a material that does not exhibit oxygen-barrier properties. Rather, the core device may be coated with a liquid form of an oxygen-barrier material, such as the liquid form of oxygen-barrier material described above, before the insulator material is injected around the core device.

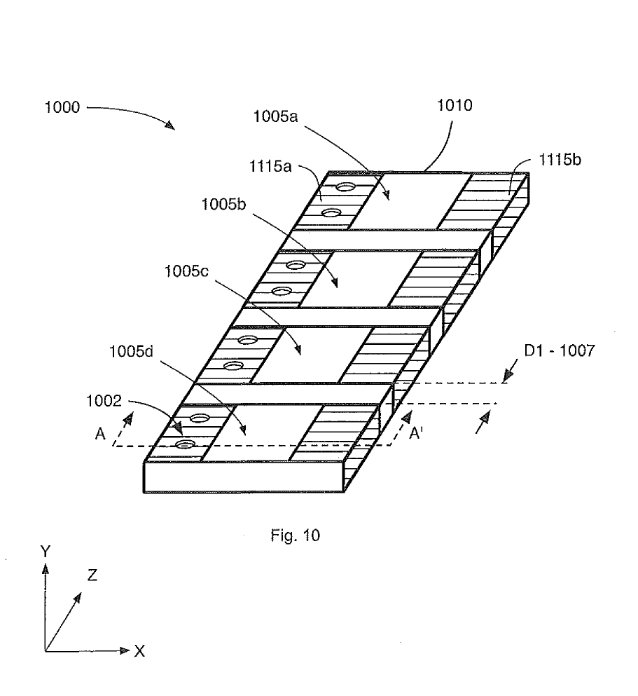

Described above are various embodiments of surface mount devices that include one core device. In alternative implementations, the various embodiments may be configured to house more the one core device, as illustrated by the surface mount device 1000 of FIG. 10.

FIG. 10 illustrates a perspective view of an exemplary multi-core surface mount device 1000 (MCSMD). The MCSMD 1000 includes four core devices 1005a-d arranged with a housing 1010. For each core device 1005a-d, a pair of contact pads 1115ab are formed on the outside surface of the housing 1010. The contact pads 1115ab may be formed as described above with reference to FIGS. 1A-1C. Apertures 1002 may be formed in the contact pads 1115ab to facilitate coupling of the respective core device 1005a-d to the contact pads 1115ab. The cross-section taken along section A-A′ of the MCSMD 1000 may be similar to the cross-section shown in FIG. 1C, which illustrates that manner in which the contact pads 115ab are coupled to the core device 1005a-d. The contact pads 1115ab enable placement of the MCSMD 1000 via surface mount soldering techniques. In one implementation, the size of an MCSMD 1000 that includes four core devices 1005a-d may be about 12 mm by 2.5 mm by 0.7 mm (0.470 in by 0.100 in by 0.028 in) in an X, Y, and Z direction, respectively. However, the X dimension may be reduced may reducing the distance between adjacent core devices. In one implementation, the distance D1 1007 between adjacent core devices 1005a-d may be about 0.635 mm (0.025 in). However, the distance may be different. For example, the distance D1 may be anywhere between about 0.127 mm to 0.635 mm (0.005 in to 0.025 in). The MCSMD 1000 facilitates the placement of a group of core devices 1005a-d in less space than would be required in the case of individual SMDS.

The MCSMD housing 1010 may comprise a C-stages oxygen barrier material, as described above. The C-staged oxygen barrier material substantially prevents oxygen outside of the housing 1010 from reaching the core devices 1005a-d. For example, the oxygen permeability of the housing 1010 may be less than approximately 0.4 cm³·mm/m²·atm·day. Such a housing material facilitates the placement of cores that tend to degrade in the presence of oxygen, such as the positive temperature coefficient (PTC) devices, described above. The characteristics of the housing material electrically insulate core devices 1005a-d from one another. The housing material may also thermally insulate respective core devices 1005a-d from one another, which is an important consideration when the core devices 1005a-d are sensitive to variations in temperature, as is the case with PTC devices.

In some embodiments, all the core devices 1005a-d are of the same type, such as PTC devices. In alternative embodiments, the core devices 1005a-d in a given housing 1010 may be different. For example, a first core device 1005a may be a PTC device, a second core device 1005b may be a resistor, a third core device 1005c may be an inductor, and a fourth core device 1005d may be a capacitor. Different core devices 1005a-d and combinations may be embedded with the housing 1010. In addition, the number of core devices 1005a-d may be greater or smaller and the core devices 1005a-d may be arranged in a different configuration. For example, the housing 1010 may have a square shape with core devices 1005a-d arranged in a square pattern. Other configurations are possible.

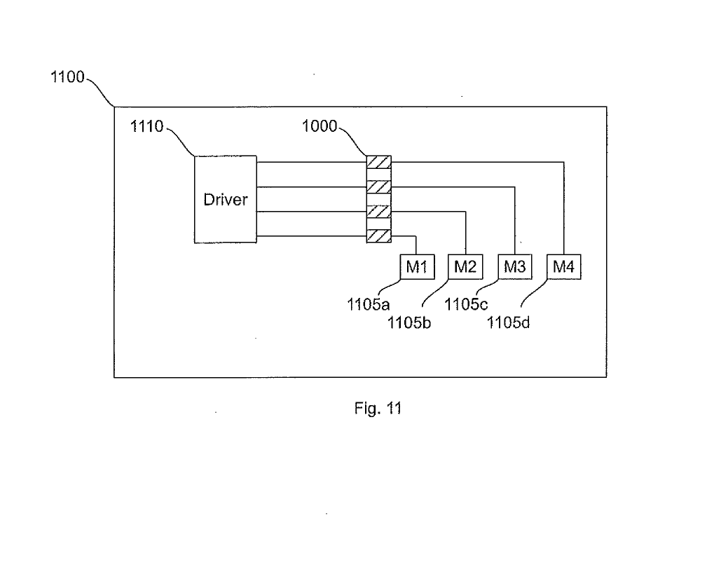

FIG. 11 is an exemplary circuit diagram 1100 of a circuit that includes the MCSMB 1000 described above. The circuit diagram 1100 includes the MCSMB 1000, a source device 1110, and a group of sinks devices 1105a-d. The source device 1110 includes four outputs coupled to a first side of the MCSMB 1000. In particular, each output is coupled to a respective first contact pad of a given core device. The sink devices 1105a-d are coupled to respective second contact pads of the core devices. Each path from source 1110 to MCSMB 1000 core device, and from MCSMB 1000 core device to sink 1105a-d is an electrically isolated path. For example, the source device 1110 may correspond to a power source, such as a USB power source. The sinks 1105a-d may correspond to USB devices, such as keyboards, cameras, hubs and the like, which may obtain power from the source device 1110. The MCSMD 1000 may include four PTC devices for protecting the source device 1110 from a short circuit condition caused by a failure of one of the sink devices 1105a-d. The thermal insulating characteristic of the housing substantially prevents heat transfer between a PTC device that is coupled to a faulty sink and other PTC devices in the housing.

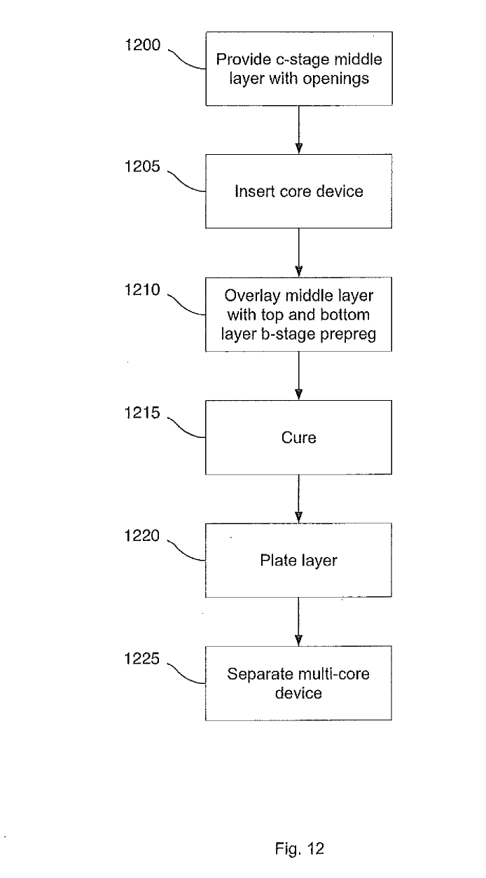

FIG. 12 illustrates a group of operations that may be utilized for manufacturing the MCSMB 1000. The operations with respect to blocks 1200-1220 may correspond to the operations 200-220 described with respect to FIG. 2. For example, at block 1200, a C-staged middle layer 310 may be provided and openings 312 may be defined in the middle layer, as shown in FIG. 3.

At block 1205, core devices 305 (FIG. 3) may be inserted into the openings 312. For example, PTC devices, resistors, capacitors, inductors, or other devices may be placed in the openings. The core devices 305 may be inserted into the openings 312 by hand, be placed in the openings 312 with pick-and-place machinery, vibratory sifting table, and/or via a different process.

At block 1210, the middle layer 310 with the inserted core devices 305 may be placed between two insulator layers 300 and 315, as shown in FIG. 3.

At block 1215, the top, middle, and bottom layers 300, 310 and 315 may be cured. In some implementations, a metal layer (not shown) may be placed over the top insulator layer 300 and under the bottom insulator layer 315. The metal layers may correspond to a copper foil. The various layers may then be subjected to a curing temperature, and pressure may be applied to the various layers to compress the layers. For example, a vacuum press or other device may be utilized to compress the various layers against one another. The curing temperature may be about 175° C. and the amount of pressure applied may be about 1.38 MPa (200 psi).

At block 1220, a metallization layer (not shown) may be formed on the top and bottom layers 300 and 315 and also the apertures that expose the ends of the individual PTC devices. For example, a copper and/or nickel layer may be deposited on the top and bottom layers. The metallization layer may be etched to define contact pads 1115ab for the MCSMB 1000. The apertures 1002 may be formed in the plating layer. The apertures 1002 may be formed via a drill, laser, or other process. The interior region of the apertures 1002 may be plated to provide an electrical pathway between the contact pads 1115ab and the core devices 1005a-d.

At block 1225, the MCSMB 1000 may be separated from the cured layers. For example, the cured layers may be cut via saw, laser or other cutting means to separate individual MCSMBs 1000. In some implementations, the cured layers are cut column-wise. This results in an MCSMB 1000 that is generally rectangular, as shown in FIG. 10. In other implementations, multiple cutting passes may be applied to separate MCSMBs 1000 of other geometries, such as a square shape. Only the number of core devices 1005a-d in the cured layers limits the number of core devices 1005a-d in a given MCSMB 1000. For example, in some implementations the cured layers may not be cut. In this case, the MCSMB 1000 will include all the core devices 1005a-d placed in the openings described above.

As shown, the various implementations overcome the problems caused by oxygen on a core device disposed inside of a surface mount device (SMD) by providing an SMD that includes an oxygen-barrier material for an insulator material. The insulator material protects the core device within the SMD from the effects of oxygen and other impurities. In some implementations, the insulator material is formulated into sheets of B-staged oxygen-barrier material and in other implementations A-staged oxygen barrier materials are utilized.

While the SMD and the method for manufacturing the SMD have been described with reference to certain embodiments, it will be understood by those skilled in the art that various changes may be made and equivalents may be substituted without departing from the scope of the claims of the application. Many other modifications may be made to adapt a particular situation or material to the teachings without departing from the scope of the claims. Therefore, it is intended that SMD and method for manufacturing the SMD are not to be limited to the particular embodiments disclosed, but to any embodiments that fall within the scope of the claims.

What is claimed is:

1. An electrical component comprising:
a plurality of core devices arranged within a housing so as to be electrically isolated from one another; and
for each of the plurality of core devices, a first contact pad and a second contact pad formed on an outside surface of the housing and electrically connected to a core device of the plurality of core devices.

2. The electrical component according to claim 1, wherein the housing comprises a C-staged oxygen-barrier insulator material that substantially encapsulates each of the plurality of core devices.

3. The electrical component according to claim 2, wherein the C-staged oxygen-barrier insulator material has an oxygen permeability of less than approximately 0.4 cm³·mm/m²·atm·day.

4. The electrical component according to claim 1, wherein at least some of the plurality of core devices are positive temperature coefficient (PTC) devices.

5. The electrical component according to claim 1, wherein at least one of the plurality of core devices is a device selected from the group of devices consisting of: a resistor, an inductor, and a capacitor.

6. The electrical component according to claim 1, wherein the electrical component is a surface mount device.

7. The electrical component according to claim 1, wherein adjacent cores of the plurality of cores are separated by a distance of less than about 0.635 mm to thereby thermally insulate adjacent cores from one another.

8. A method for producing an electrical component comprising:
providing a plurality of layers including a first layer that is B-staged and a second layer that defines a plurality of openings for receiving a plurality of core devices;
inserting the plurality of core devices in the plurality of openings defined by the second layer;
covering the second layer and the plurality of core devices with the first layer that is B-staged;
curing the first layer and second layer until the first layer that is B-staged becomes C-staged;
separating the cured first and second layers into housing portions that each include a plurality of core devices, wherein the plurality of core devices are electrically isolated from one another.

9. The method according to claim 8, further comprising forming, for each of the plurality of core devices, a first contact pad and a second contact pad formed on an outside surface of the housing and electrically connected to a core device of the plurality of core devices.

10. The method according to claim 8, wherein the C-staged oxygen-barrier insulator material has an oxygen permeability of less than approximately 0.4 cm³·mm/m²·atm·day.

11. The method according to claim 8, wherein at least some of the plurality of core devices are positive temperature coefficient (PTC) devices.

12. The method according to claim 8, wherein at least one of the plurality of core devices is a device selected from the group of devices consisting of: a resistor, an inductor, and a capacitor.

13. The method according to claim 8, wherein the electrical component is a surface mount device.

14. The electrical component according to claim 8, wherein adjacent cores of the plurality of cores are separated by a distance of less than about 0.635 mm to thereby thermally insulate adjacent cores from one another.

15. A circuit comprising:
a first electrical component comprising:
a plurality of core devices arranged within a housing so as to be electrically isolated from one another; and
for each of the plurality of core devices, a first contact pad and a second contact pad formed on an outside surface of the housing and electrically connected to a core device of the plurality of core devices;
for each of the plurality of core devices, an input circuit coupled to the first contact pad; and
for each of the plurality of core devices, an output circuit coupled to the second contact pad.

16. The circuit according to claim 15, wherein the housing comprises a C-staged oxygen-barrier insulator material that substantially encapsulates each of the plurality of core devices.

17. The circuit according to claim 16, wherein the C-staged oxygen-barrier insulator material has an oxygen permeability of less than approximately 0.4 cm³·mm/m²·atm·day.

18. The circuit according to claim 15, wherein at least some of the plurality of core devices are positive temperature coefficient (PTC) device.

19. The circuit according to claim 15, wherein at least one of the plurality of core devices is a device selected from the group of devices consisting of: a resistor, an inductor, and a capacitor.

20. The circuit according to claim 15, wherein adjacent cores of the plurality of cores are separated by a distance of less than about 0.635 mm to thereby thermally insulate adjacent cores from one another.
